(19) United States
(12) Patent Application Publication
(10) Pub. No.: US 2007/0052103 A1
(43) Pub. Date: Mar. 8, 2007

(54) TiN layer structures for semiconductor devices, methods of forming the same, semiconductor devices having TiN layer structures and methods of fabricating the same

(75) Inventors: Ho-Ki Lee, Seongnam-si (KR); Kwang-Jin Moon, Suwon-si (KR); Hyun-Su Kim, Suwon-si (KR); Sung-Tae Kim, Seoul (KR); Sang-Woo Lee, Seoul (KR); Eun-Ok Lee, Incheon (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/515,876

(22) Filed: Sep. 6, 2006

(30) Foreign Application Priority Data
Sep. 6, 2005 (KR) 10-2005-0082825

(51) Int. Cl. H01L 23/52

(52) U.S. Cl. 257/758

(57) ABSTRACT

TiN layer structures for semiconductor devices, methods of forming TiN layer structures, semiconductor devices having TiN layer structures and methods of fabricating semiconductor devices are disclosed. The TiN layer structure for a semiconductor device includes a TiN base layer and a conductive capping layer. The TiN base layer is formed on a substrate. The conductive capping layer is formed on the TiN base layer by laminating unit layers repeatedly.

### PRIORITY STATEMENT

This non-provisional U.S. patent application claims priority under 35 U.S.C. §119 to Korean Patent Application No. 10-2005-0082825 filed on Sep. 6, 2005, in the Korean Intellectual Property Office (KIPO), the entire contents of which are incorporated herein by reference.

### BACKGROUND

### Description of the Related Art

As related art semiconductor devices becomes increasingly integrated, properties of dielectric layers used in related art semiconductor devices may required lower temperature processes with a lower heat budget. A TiN layer used to form various barriers, electrodes, etc., of related art semiconductor devices is formed at a lower temperature using a chemical vapor deposition (CVD) process.

When the TiN layer is formed at lower temperature using CVD, the resistance value of the TiN layer increases as the process temperature decreases. In addition, when the TiN layer is exposed to the atmosphere, the TiN layer may oxidize over time, and thus, resistance of the TiN layer may increase.

To suppress an increase or decrease in resistance of the TiN layer, a related art cyclic CVD process, in which CVD processes are repeatedly performed, or an ALD (atomic layer deposition) process may be used. In the cyclic CVD process or the ALD process, the resistance of the TiN layer may be maintained at lower temperatures. However, production yield when using the cyclic CVD process or the ALD process may decrease and/or be insufficient.

### SUMMARY

Example embodiments relate to semiconductor devices, for example, TiN layer structures for semiconductor devices, methods of forming the same, semiconductor devices having a TiN layer structure, and methods of fabricating the same.

At least one example embodiment provides a TiN layer structure for semiconductor devices having improved production yield and/or electrical characteristics (e.g., resistance).

At least one other example embodiment provides a semiconductor device having a TiN layer structure. At least one other example embodiment provides a method of forming a TiN layer structure. Yet at least one other example embodiment provides a method of fabricating a semiconductor device.

According to at least one example embodiment, a TiN layer structure of a semiconductor device may include a TiN base layer formed on a substrate and a conductive capping layer. The conductive capping layer may have a multilayer structure including a plurality of unit layers, and may be formed by repeatedly laminating at least one unit layer.

According to at least one other example embodiment, a semiconductor device may include an interlayer insulating layer, a metal barrier layer and a contact plug. The interlayer insulating layer may be formed between a lower conductive layer and an upper conductive layer. The interlayer insulating layer may have a contact hole for connecting the lower conductive layer and the upper conductive layer to each other. The metal barrier may be formed on an inner wall of the contact hole and may have a TiN base layer and a conductive capping layer formed on the TiN base layer. The conductive capping layer may have a multilayer structure including a plurality of unit layers, and may be formed by repeatedly laminating at least one unit layer. The contact plug may be formed on the metal barrier to bury the contact hole.

According to at least one other example embodiment, a semiconductor device may include a capacitor having a lower electrode, an upper electrode and a dielectric layer. The upper electrode may be formed above the lower electrode, and the dielectric layer may be interposed between the lower electrode and the upper electrode. At least one of the lower electrode and the upper electrode may include a TiN base layer and a conductive capping layer. The conductive capping layer may have a multilayer structure including a plurality of unit layers, and may be formed by repeatedly laminating at least one unit layer.

At least one other example embodiment provides a method of forming a TiN layer structure of a semiconductor device. In at least this example embodiment, a TiN base layer may be formed on a substrate. A conductive capping layer may be formed on the TiN base layer by laminating at least one unit layer on an upper surface of the TiN base layer repeatedly.

At least one other example embodiment provides a method of fabricating a semiconductor device. In at least this example embodiment, an interlayer insulating layer may be formed on a lower conductive layer. A contact hole may be formed to penetrate the interlayer insulating layer to expose an upper surface of the lower conductive layer. A TiN base layer may be formed on an inner wall of the contact hole and a conductive capping layer may be formed by laminating at least one unit layer on an upper surface of the TiN base layer repeatedly to form a resultant metal barrier. A contact plug may be formed to bury the contact hole, and an upper conductive layer may be connected to the contact plug.

At least one other example embodiment provides a method of fabricating a semiconductor device. In at least this example embodiment, a lower electrode may be formed on a substrate. A dielectric layer may be formed on the lower electrode, and an upper electrode may be formed on the dielectric layer. At least one of the forming of the lower electrode and the forming of the upper electrode may include forming a TiN base layer and forming a conductive capping layer by laminating at least one unit layer on an upper surface of the TiN base layer repeatedly.

### BRIEF DESCRIPTION OF THE DRAWINGS

Example embodiments will become more apparent by describing in detail the attached drawings in which:

FIG. 1 is a cross-sectional view illustrating a TiN layer structure of a semiconductor device, according to an example embodiment;

FIG. 2 is a cross-sectional view illustrating a semiconductor device having a contact having a TiN layer structure, according to an example embodiment;

FIG. 3 is a cross-sectional view illustrating a semiconductor device including a capacitor at least a portion of which has a TiN layer structure, according to an example embodiment;

FIGS. 4A and 4B are cross-sectional views illustrating a method of forming the TiN layer structure of a semiconductor device, according to an example embodiment;

FIGS. 5A to 5E are cross-sectional views illustrating a method of fabricating the semiconductor device, according to an example embodiment;

FIGS. 6A to 6D are cross-sectional views illustrating a method of fabricating the semiconductor device, according to another example embodiment; and

FIG. 7 is a graph illustrating an increasing rate of resistance over time for related art samples fabricated according to the related art and a test sample fabricated in accordance with an example embodiment.

### DETAILED DESCRIPTION OF EXAMPLE EMBODIMENTS

Various example embodiments will now be described more fully with reference to the accompanying drawings. In the drawings, the thicknesses of layers and regions are exaggerated for clarity.

Detailed illustrative example embodiments are disclosed herein. However, specific structural and functional details disclosed herein are merely representative for purposes of describing example embodiments. The present invention may, however, may be embodied in many alternate forms and should not be construed as limited to only the example embodiments set forth herein.

Accordingly, while example embodiments are capable of various modifications and alternative forms, example embodiments are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element or layer is referred to as being “formed on” another element or layer, it can be directly or indirectly formed on the other element or layer. That is, for example, intervening elements or layers may be present. In contrast, when an element or layer is referred to as being “directly formed on” to another element, there are no intervening elements or layers present. Other words used to describe the relationship between elements or layers should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the FIGS. For example, two FIGS. shown in succession may in fact be executed substantially concurrently or may sometimes be executed in the reverse order, depending upon the functionality/acts involved.

According to at least some example embodiments, a TiN base layer may be a TiN layer formed on an upper surface of a substrate to a thickness, for example, a TiN layer corresponding to a thickness excluding a conductive capping layer from a TiN layer structure. A base TiN layer may be formed (e.g., sequentially formed) over a period of time using a fabrication method, according to at least one example embodiment.

According to at least some example embodiments, a unit layer may be a layer formed repeatedly to form the conductive capping layer. For example, the conductive capping layer may be formed by laminating a plurality of unit layers. In a fabrication method, according to at least one example embodiment, a layer may be formed at completion of one cycle of a process of forming a capping layer.

According to at least some example embodiments, a substrate may be a semiconductor substrate or a semiconductor substrate on which various layers, (e.g., one or more oxide layers, nitride layers, etc.) are formed.

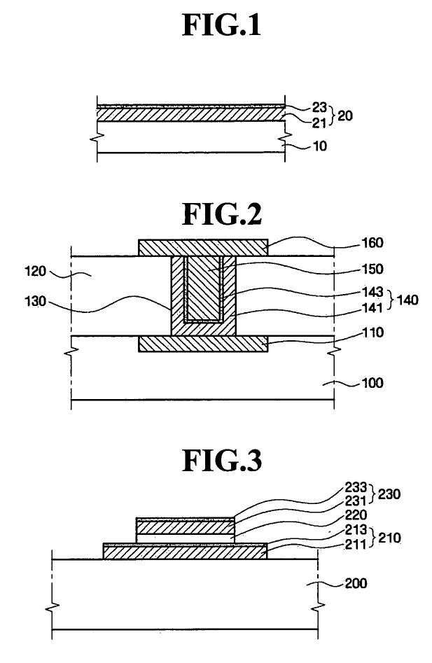

FIG. 1 is a cross-sectional view illustrating a TiN layer structure for a semiconductor device, according to an example embodiment. Referring to FIG. 1, a TiN layer 20 of a semiconductor device, according to an example embodiment, may include a TiN base layer 21 and a conductive capping layer 23. The TiN base layer 21 may be formed on a substrate 10 and the conductive capping layer 23 may be formed on the TiN base layer 21. Although not shown in the drawing, the conductive capping layer 23 may have a multilayer structure in which a plurality of unit layers are laminated, for example, repeatedly. The TiN base layer 21 may be formed to have a columnar or cylindrical shape or structure.

The TiN layer 20 having the structure described above may have improved resistance characteristics relative to related art structures. In addition or alternatively, oxidation of the TiN layer 20 may be suppressed and variation characteristics of a resistance with respect to time may be improved, which may improve quality of the TiN layer 20. Example embodiments may also improve production yield in fabrication processes.

The thickness of the TiN base layer 21 and the thickness of the conductive capping layer 23, according to example embodiments, may be adjusted according to the application of the TiN structure. For example, the thickness of the conductive capping layer 23 may be approximately 5 to approximately 20%, inclusive, of a total thickness of the TiN layer 20. If the thickness of the conductive capping layer 23 is greater than or equal to approximately 5% of the total thickness of the TiN layer 20, the conductive capping layer 23 may have improved characteristics. On the other hand, if the thickness of the conductive capping layer 23 is less than or equal to approximately 20% of the total thickness of the TiN layer 20, the production yield in the fabrication process may improve. However, example embodiments are not limited to the conductive capping layer 23 having a thickness of approximately 5 to approximately 20%, inclusive, of the total thickness of the TiN layer 20. Instead, a conductive capping layer having a thickness other than the thickness range described above may be possible.

Furthermore, the thickness of each unit layer forming the conductive capping layer 23 may be approximately 3 to approximately 8 Å, inclusive. If the thickness of the unit layer is greater than or equal to approximately 3 Å, the production yield in the fabrication process may improve. If the thickness of the unit layer is less than or equal to approximately 8 Å, for example, oxidation of the TiN layer may be suppressed from being oxidized, and thus, improved characteristics may be obtained. However, example embodiments are not limited to the unit layer having a thickness of approximately 3 to approximately 8 Å, inclusive. Alternatively, a unit layer having a thickness other than the thickness range described above may be used. In at least one example embodiment, to form conductive capping layer 23 having the above-described thickness, about five to about ten unit layers may be laminated.

The conductive capping layer 23 may be made of TiN or Ti, but is not limited thereto.

FIG. 2 is a cross-sectional view illustrating a semiconductor device having a contact structure which includes the above-described TiN layer structure. In FIG. 2, in order to show the contact structure in detail, the contact structure is shown in a size larger than an actual size.

Referring to FIG. 2, a semiconductor device, according to an example embodiment, may include a contact structure having a metal barrier 140. The metal barrier 140 may have the above-described TiN layer structure. In at least this example embodiment, a ‘contact’ refers to any type of electrical connection for connecting a lower conductive layer to an upper conductive layer (e.g., contact plug, a wire, a bump, a solder ball, a bonding wire, etc.). In at least one example embodiment, a ‘contact’ may include a via by which a lower wiring line and an upper wiring line are connected.

In at least this example embodiment, a semiconductor device may include a contact formed within an interlayer insulating layer 120 to connect a lower conductive layer 110 and an upper conductive layer 160. The contact may include a metal barrier 140 and a contact plug 150. The metal barrier layer 140 may be formed on an inner wall of a contact hole 130. The contact hole 130 may be formed within the interlayer insulating layer 120. The contact plug 150 may bury the contact hole 130. The metal barrier 140 may include a TiN barrier 141 and a conductive capping layer 143. Because the metal barrier 140 may have the same or substantially the same structure as the TiN layer structure described above with reference to FIG. 1, a detailed explanation thereof will be omitted for the sake of brevity. The lower conductive layer 110 may be formed within a portion of a substrate 100.

FIG. 3 is a cross-sectional view illustrating a semiconductor device including a capacitor having a TiN layer structure, according to an example embodiment.

Referring to FIG. 3, the semiconductor device may include a capacitor having a lower electrode 210, an upper electrode 230 and a dielectric layer 220 interposed between the lower electrode 210 and the upper electrode 230. The semiconductor device of FIG. 3 may be formed on a substrate 200. The capacitor shown in FIG. 3 may be, for example, a flat-type capacitor; however, any other suitable structure (e.g., trench-type capacitors, concave-type capacitors, etc.) may be used.

At least one of the lower electrode 210 and the upper electrode 230 may include a TiN layer structure. In this example embodiment, the lower electrode 210 may include a TiN barrier 211 and a conductive capping layer 213, and the upper electrode 230 may include a TiN barrier 231 and a conductive capping layer 233. Because the lower electrode 210 and/or the upper electrode 230 may have the same or substantially the same structure as the TiN layer structure described above with reference to FIG. 1, a detailed explanation thereof will be omitted for the sake of brevity.

To obtain a desired capacitance when the size of a capacitor is reduced, the dielectric layer 220 may be a dielectric layer (e.g., a high dielectric layer) having high dielectric constant (high-k). The dielectric layer 220 may be comprised of, for example, HfO₂, HfSiO, HfAlO, ZrO₂, ZrSiO, ZrAlO, Ta₂O₅, TiO₂, Al₂O₃, Nb₂O₅, CeO₂, Y₂O₃, INO₃, IrO₂, SrTiO₃, PbTiO₃, SrRuO₃, CaRuO₃, (Ba, Sr)TiO₃, Pb(Zr,Ti)O₃, (Pb,La)(Zr,Ti)O₃, (Sr, Ca)RuO₃, a laminated layer (e.g., a laminated structure) obtained by laminating layers comprised of these or similar materials.

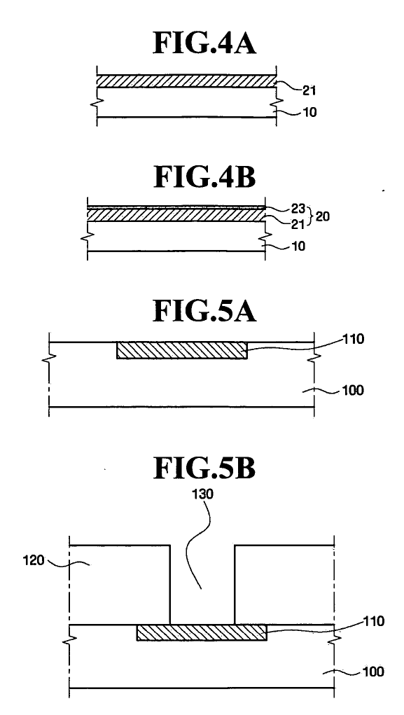

A method of forming the TiN layer and a method of fabricating the semiconductor device, according to example embodiments will be described with reference to FIGS. 4A and 4B, 5A to 5E, and 6A to 6D.

FIGS. 4A and 4B are cross-sectional views illustrating a method of forming a TiN layer structure of a semiconductor device, according to an example embodiment.

Referring to FIG. 4A, the TiN base layer 21 may be formed on an upper surface of the substrate 10. The TiN base layer 21 may be formed at a temperature of less than or equal to about 600° C. to reduce a heat budget. In at least one example embodiment, TiN base layer 21 may be formed at a temperature of less than or equal to about 500° C.

The TiN base layer 21 may be formed using, for example, a related art chemical vapor deposition method. In at least this example, the substrate 10 may be heated and purged with, for example, N₂ gas. The TiN base layer 21 may be formed on the substrate 10 to a thickness using TiCl₄ and NH₃ as reaction gases. The TiN base layer 21 may be purged with, for example, N₂ gas to discharge the unreacted gas. NH₃ gas may be injected, to nitrize any Ti—Cl bonds remaining on the TiN base layer 21 and discharge any impurities, (e.g., chlorine remaining on the TiN base layer 21) to the outside.

The TiN base layer 21 formed by the CVD method may be formed in a columnar or cylindrical shape. In addition, the TiN base layer 21 may be formed using a continuous process until the TiN base layer 21 has a desired thickness. However, alternatively, the process may not be continuous.

As shown in FIG. 4B, a conductive capping layer 23 may be formed on an upper surface of the TiN base layer 21. The conductive capping layer 23 may be formed by laminating at least one unit layer repeatedly.

The conductive capping layer 23 may be formed using, for example, a cyclic chemical vapor deposition (cyclic CVD) method, an ALD method, or the like.

For example, in a cyclic CVD method, the above described CVD processes may be repeated several times, but the duration of each process may be reduced. In one example, a substrate, on which a TiN base layer is formed, may be placed in a reaction chamber and purged with, for example, N₂ gas. Reaction gases TiCl₄ and NH₃ may be injected into the reaction chamber to evaporate a TiN layer. Unreacted gas may be purged using, for example, N₂ gas and nitrized by injecting additional NH₃ gas, to complete one cycle. A layer formed in the one cycle may correspond to an above-described unit layer. The unit layer may be formed to have a thickness in a range of approximately 3 to approximately 8 Å, inclusive, by properly controlling the injection amount of TiCl₄ and NH₃, the process time or the like. In at least one example embodiment, about five to about ten cycles may be performed to form a conductive capping layer 23 having a desired thickness.

In addition, as an example of the ALD method, a substrate, on which a TiN base layer is formed, may be placed in a reaction chamber and purged with, for example, N₂ gas. Reaction gas TiCl₄ may be injected into the reaction chamber and evaporated on the substrate. NH₃ may be inserted into the reaction chamber to react with TiCl₄ and form a TiN layer. Unreacted gas may be purged using, for example, N₂ gas, and may be nitrized by injecting additional NH₃ gas. The processes described above may be repeated until the conductive capping layer 23 is formed to a desired thickness.

The process of forming the conductive capping layer 23, according to an example embodiment, may be performed in the same chamber as in the process of forming the TiN base layer 21.

In a method of fabricating a TiN layer structure, according to at least one example embodiment, because the CVD method and the cyclic CVD method or the ALD method are applied sequentially and/or because the cyclic CVD method or the ALD method is applied to only the conductive capping layer, the resistance of the TiN layer may decrease, resistance change over time may be reduced and/or production yield may improve.

The thickness of the conductive capping layer 23, which is formed by laminating the unit layers, may be approximately 5 to approximately 20%, inclusive, of a total thickness of the TiN layer 20 including the TiN base layer 21 and the conductive capping layer 23. In at least this example embodiment, an explanation of the conductive capping layer 23 is the same or substantially the same as the above explanation on the TiN layer structure, and thus, has been omitted for the sake of brevity.

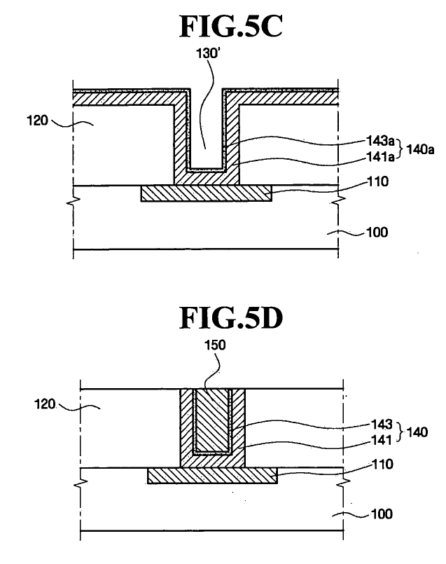

A method of fabricating the semiconductor device, according to an example embodiment will be described with reference to FIGS. 5A to 5E. In FIGS. 5A to 5E, to show the contact structure in more detail, the contact structure is shown in a size larger than an actual size.

Referring to FIG. 5A, a lower conductive layer 110 may be formed on a substrate 100. The lower conductive layer 110 may be, for example, source/drain regions formed within a semiconductor substrate or a metal wiring layer formed in a substrate.

As shown in FIG. 5B, an interlayer insulating layer 120 covering the lower conductive layer 110 may be formed, and the contact hole 130 may be formed in the interlayer insulating layer 120 to expose an upper surface of the lower conductive layer 110.

As shown in FIG. 5C, a metal barrier 140a may be formed on an inner wall of the contact hole 130. The metal barrier 140a may have the same or substantially the same structure as the TiN layer structure described above, and the metal barrier 140a may be formed by forming a TiN base layer 141a and forming a conductive capping layer 143a. The metal barrier 140a may be formed using the same or substantially the same method described above, and thus, a detail explanation thereof will be omitted for the sake of brevity.

On the other hand, although not shown, other layers, such as an anti-diffusion layer, an adhesive layer, a seed layer, etc. may be laminated on a lower or upper surface of the metal barrier 140a.

Referring to FIG. 5D, a contact plug 150 burying the contact hole 130, on which the metal barrier 140 is formed, may be formed. The contact plug 150 may be formed by burying a contact hole with a conductive material such that an upper surface of an interlayer insulating layer is covered therewith and planarizing the conductive material.

As shown in FIG. 5E, the upper conductive layer 160 connected to the contact plug 150 may be formed.

A process of forming wiring lines, a process of forming a passive layer on a substrate, and a process of packaging the substrate, which are well-known to those skilled in the art, may be performed to form a semiconductor device.

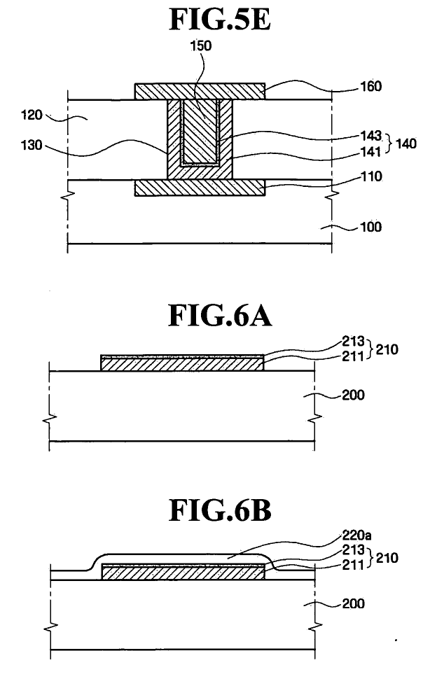

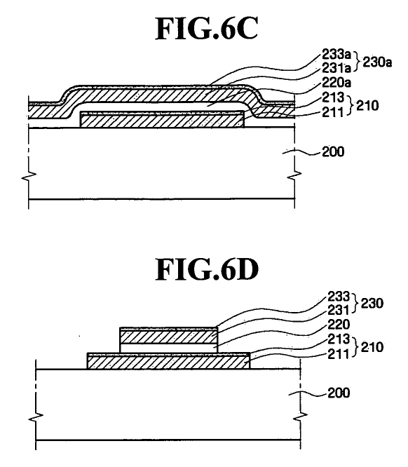

FIGS. 6A to 6D illustrate a method of fabricating a semiconductor device, according to an example embodiment.

Referring to FIG. 6A, a lower electrode of a capacitor may be formed on a substrate 200. Because the lower electrode 210 is formed to include the TiN base layer 211 and the conductive capping layer 213 in the same or substantially the same manner as described above, a detailed explanation thereof will be omitted for the sake of brevity.

As shown in FIG. 6B, a dielectric layer 220a may be formed on the lower electrode 210. To obtain a desired capacitance, even when the size of a capacitor is reduced, the dielectric layer 220a may be a high dielectric layer having high dielectric constant (high-k). The dielectric characteristic of high dielectric layers may result from the increased ionic polarization. In at least this example embodiment, the dielectric layer 220a may be comprised of, for example, HfO₂, HfSiO, HfAlO, ZrO₂, ZrSiO, ZrAlO, Ta₂O₅, TiO₂, Al₂O₃, Nb₂O₅, CeO₂, Y₂O₃, InO₃, IrO₂, SrTiO₃, PbTiO₃, SrRuO₃, CaRuO₃, (Ba,Sr)TiO₃, Pb(Zr, Ti)O₃, (Pb,La)(Zr,Ti)O₃, or (Sr,Ca)RuO₃, a laminated layer (e.g., a laminated structure) formed by laminating layers made of these or similar materials.

The dielectric layer 220a may be formed by using a CVD method. In at least this example embodiment, the CVD method may include, for example, an ALD method and a metal organic chemical vapor deposition (MOCVD) method.

As shown in FIG. 6C, an upper electrode 230a may be formed on a dielectric layer 220a. Because the upper electrode 230a is formed to include the TiN base layer 231a and the conductive capping layer 233a in the same or substantially the same manner as described above, a detailed explanation thereof will be omitted for the sake of brevity. In addition, a method of forming the upper electrode 230a may be the same or substantially the same as the method of forming the above-described TiN layer structure, and thus, a detailed explanation thereof will be omitted for the sake of brevity.

As shown in FIG. 6D, an etching process may be performed to expose a part of an upper surface of the lower electrode 210 and for a capacitor.

The process of forming wiring lines, the process of forming a passive layer on a substrate and the process of packaging the substrate, which are well-known to those skilled in the art, may be performed to form a semiconductor device.

Fabrication examples for evaluating properties of the TiN layer structure, according to at least some example embodiments will be described below.

### FABRICATION EXAMPLE

To fabricate a first test sample, a TiN base layer is formed to have a thickness of about 160 Å using the CVD method and a conductive capping layer is formed to have a thickness of about 40 Å using the cyclic CVD method at a temperature of 500° C. The thickness of each unit layer in this test sample is about 7.5 Å.

### FIRST COMPARATIVE FABRICATION EXAMPLE

To fabricate a first comparative fabrication sample, a TiN layer is formed to have a thickness of about 200 Å using only the CVD method applied in the above fabrication example without separately forming a conductive capping layer.

### SECOND COMPARATIVE FABRICATION EXAMPLE

To fabricate a second comparative fabrication sample, a TiN layer is formed to have a thickness of about 200 Å using only the cyclic CVD method applied in the above fabrication example without separately forming a conductive capping layer.

### THIRD COMPARATIVE FABRICATION EXAMPLE

To fabricate a third fabrication sample, a primary TiN layer is formed to have a thickness of about 40 Å using the cyclic CVD method and a secondary TiN layer is formed on the primary TiN layer to have a thickness of about 160 Å using the CVD method.

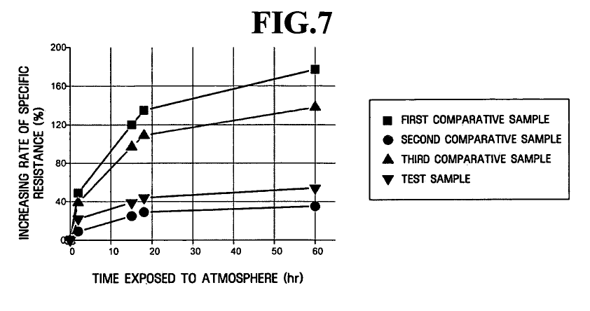

For the test sample, the first comparative sample, the second comparative sample, and the third comparative sample, a resistance, processing time per wafer, production yield, and a variation of a sheet resistance with respect to time change have been measured. The resistance, processing time per wafer and production yield are shown in table 1. The variation of the sheet resistance with respect to the time change is shown in FIG. 7.

TABLE 1

| | specific | processing time | production |
|---|---|---|---|
| sample | resistance | per wafer | yield |
| test sample | 480 | 200 | 15.00 |
| first comparative | 950 | 170 | 17.65 |
| sample | | | |
| second comparative | 410 | 290 | 10.34 |
| sample | | | |
| third comparative | 832 | 200 | 15.00 |
| sample | | | |

Referring to table 1, with respect to the first comparative sample fabricated using only the CVD method without forming the conductive capping layer, the resistance is lower, but the production yield may be sufficient. On the other hand, with respect to the second comparative sample fabricated using only the cyclic CVD method, the resistance may be sufficient, but the production yield is lower. With respect to the test sample, fabricated in accordance with an example embodiment, the production yield is similar to that of the first comparative sample and the resistance is similar to that of the second comparative sample. Further, with regard to the third comparative sample in which the TiN layer is formed in an order reverse to that in the test sample, the production yield may be the same as that of the test sample, but the specific resistance is substantially greater than that of the test sample.

In addition, referring to FIG. 7, the increasing rate of the resistance change over time for the test sample is more desirable as compared with those of the first and third comparative samples, and is substantially similar to that of the second comparative sample.

As describe above, in a TiN layer structure, according to an example embodiment, various characteristics, such as resistance, the variation of the sheet resistance with respect to time change and/or production yield may be improved. Thus using a TiN layer, according to an example embodiment, may improve characteristics of semiconductor devices.

Although example embodiments have been described in connection with the drawings, it will be apparent to those skilled in the art that various modifications and changes may be made thereto without departing from the scope and spirit of the present invention. Therefore, it should be understood that the above-described example embodiments are not limitative, but illustrative.

What is claimed is:

1. A TiN layer structure of a semiconductor device, comprising:
a TiN base layer; and
a conductive capping layer formed on the TiN base layer, the conductive capping layer having a multi-layer structure including plurality of stacked unit layers.

2. The TiN layer structure of claim 1, wherein the TiN base layer has a columnar or cylindrical shape.

3. The TiN layer structure of claim 1, wherein the thickness of the conductive capping layer is approximately 5% to approximately 20%, inclusive, of a total thickness of the TiN layer structure.

4. The TiN layer structure of claim 1, wherein the conductive capping layer is comprised of TiN or Ti.

5. The TiN layer structure of claim 1, wherein the thickness of each of the unit layers is approximately 3 Å to approximately 8 Å, inclusive.

6. The TiN layer structure of claim 1, wherein the conductive capping layer is formed by repeatedly laminating at least one unit layer between five and ten times.

7. A semiconductor device comprising:
an interlayer insulating layer formed between a lower conductive layer and an upper conductive layer and having a contact hole connecting the lower conductive layer and the upper conductive layer;
a metal barrier is formed on an inner wall of the contact hole and including the TiN structure of claim 1; and
a contact plug is formed on the metal barrier to bury the contact hole.

8. The semiconductor device of claim 7, wherein the TiN base layer has a columnar or cylindrical shape.

9. The semiconductor device of claim 7, wherein the thickness of the conductive capping layer is approximately 5% to approximately 20%, inclusive, of a total thickness of the metal barrier.

10. The semiconductor device of claim 7, wherein the conductive capping layer is comprised of TiN or Ti.

11. The semiconductor device of claim 7, wherein the thickness of the unit layer is approximately 3 Å to approximately 8 Å, inclusive.

12. The semiconductor device of claim 7, wherein the conductive capping layer is formed by repeatedly laminating at least one unit layer between five and ten times.

13. A semiconductor device comprising:
a capacitor having a lower electrode, an upper electrode formed above the lower electrode and a dielectric layer interposed between the lower electrode and the upper electrode, at least one of the lower electrode and the upper electrode including the TiN structure of claim 1.

14. The semiconductor device of claim 13, wherein the TiN base layer has a columnar or cylindrical shape.

15. The semiconductor device of claim 13, wherein the thickness of the conductive capping layer is approximately 5% to approximately 20%, inclusive, of a total thickness of the lower electrode or the upper electrode.

16. The semiconductor device of claim 13, wherein the conductive capping layer is comprised of TiN or Ti.

17. The semiconductor device of claim 13, wherein the thickness of each of the unit layers is approximately 3 Å to approximately 8 Å, inclusive.

18. The semiconductor device of claim 13, wherein the conductive capping layer is formed by repeatedly laminating at least one unit layer between five and ten times.

19. A method of forming a TiN layer structure of a semiconductor device, comprising:
forming a TiN base layer; and
forming a conductive capping layer by repeatedly laminating at least one unit layer on an upper surface of the TiN base layer.

20. The method of claim 19, wherein the TiN layer structure is formed at a temperature of less than or equal to approximately 600° C.

21. The method of claim 19, wherein the TiN layer structure is formed at a temperature of less than or equal to approximately 500° C.

22. The method of claim 19, wherein the thickness of the conductive capping layer is approximately 5% to of less than or equal to approximately 20%, inclusive, of a total thickness of the TiN layer structure.

23. The method of claim 19, wherein the conductive capping layer is comprised of TiN or Ti.

24. The method of claim 19, wherein the TiN base layer is formed using a CVD method, and the conductive capping layer is formed using a cyclic CVD method or an ALD method.

25. The method of claim 19, wherein the conductive capping layer is formed using a cyclic CVD method.

26. The method of claim 19, wherein the thickness of each of the unit layers is approximately 3 Å to approximately 8 Å.

27. The method of claim 19, wherein the at least one unit layer is laminated between five and ten times.

28. A method of fabricating a semiconductor device, comprising:
forming an interlayer insulating layer on a lower conductive layer;
forming a contact hole penetrating the interlayer insulating layer to expose an upper surface of the lower conductive layer;
forming a metal barrier having a TiN layer structure using the method of claim 19;
forming a contact plug burying the contact hole on which the metal barrier is formed; and
forming an upper conductive layer connected to the contact plug.

29. The method of claim 28, wherein the forming of the metal barrier is performed at a temperature of less than or equal to approximately 600° C.

30. The method of claim 28, wherein the forming of the metal barrier is performed at a temperature of less than or equal to approximately 500° C.

31. The method of claim 28, wherein the thickness of the conductive capping layer is approximately 5% to approximately 20%, inclusive, of a total thickness of the metal barrier.

32. The method of claim 28, wherein the conductive capping layer is comprised of TiN or Ti.

33. The method of claim 28, wherein the TiN base layer is formed using CVD method, and the conductive capping layer is formed using a cyclic CVD method or an ALD method.

34. The method of claim 28, wherein the conductive capping layer is formed using a cyclic CVD method.

35. The method of claim 28, wherein the thickness of each of the unit layers is approximately 3 Å to approximately 8 Å, inclusive.

36. The method of claim 28, wherein the at least one unit layer is laminated between five and ten times.

37. A method of fabricating a semiconductor device, comprising:
forming a lower electrode on a substrate;
forming a dielectric layer on the lower electrode; and
forming an upper electrode on the dielectric layer, wherein
at least one of the lower electrode and the upper electrode is formed using the method of claim 19.

38. The method of claim 37, wherein at least one of the lower electrode and the upper electrode is formed at a temperature of less than or equal to approximately 600° C.

39. The method of claim 37, wherein at least one of the lower electrode and the upper electrode is performed at a temperature of less than or equal to approximately 500° C.

40. The method of claim 37, wherein the thickness of the conductive capping layer is approximately 5% to approximately 20%, inclusive of a total thickness of at least one of the lower electrode or the upper electrode.

41. The method of claim 37, wherein the conductive capping layer is comprised of TiN or Ti.

42. The method of claim 37, wherein the TiN base layer is formed using a CVD method, and the conductive capping layer is formed using a cyclic CVD method or an ALD method.

43. The method of claim 37, wherein the conductive capping layer is formed using a cyclic CVD method.

44. The method of claim 37, wherein the thickness of each of the unit layers is approximately 3 Å to approximately 8 Å, inclusive.

45. The method of claim 37, wherein the at least one unit layer is laminated between five and ten times.
